(19) United States
(12) Patent Application Publication
(10) Pub. No.: US 2020/0020795 A1
(43) Pub. Date: Jan. 16, 2020

(54) SELF-ALIGNED GATE CUT FOR OPTIMAL POWER AND ROUTING

(71) Applicant: QUALCOMM Incorporated, San Diego, CA (US)

(72) Inventors: Junjing BAO, San Diego, CA (US); Ye LU, San Diego, CA (US); Haining YANG, San Diego, CA (US); Hyeokjin LIM, San Diego, CA (US)

(21) Appl. No.: 16/033,597

(22) Filed: Jul. 12, 2018

(51) Int. Cl. H01L 29/78; H01L 21/8238; H01L 21/768; H01L 21/321

(52) U.S. Cl. CPC H01L 29/785; H01L 21/3212; H01L 21/76897; H01L 21/823821

(57) ABSTRACT

A semiconductor device includes a substrate, a gate region formed on the substrate, a self-aligned gate cut formed in the gate region, and a middle of line (MOL) area formed on the gate region, wherein the self-aligned gate cut provides critical dimensions in a range from 5 nm to 30 nm. The self-aligned gate cut reduces capacitance and power, provides flexibility in placement of the MOL area, and reduces local routing congestion.

### FIELD

Aspects of the disclosure relate to semiconductor devices and, more specifically, to apparatus and method of self-aligned gate cut semiconductor devices for optimal power and routing.

### BACKGROUND

Transistors are essential components in modern electronic devices. Large numbers of transistors are employed in integrated circuits (ICs) in many modern electronic devices. For example, components such as central processing units (CPUs) and memory systems each employ a large quantity of transistors for logic circuits and memory devices. As electronic devices become more complex in functionality, so does the need to include a greater number of transistors in such devices. However, as electronic devices are required to provide in increasingly smaller packages, such as in mobile devices, for example, there is a need to provide a greater number of transistors in a smaller IC chip. This increase in the number of transistors is achieved in part through continued efforts to miniaturize transistors in ICs (i.e., placing increasingly more transistors into the same amount of space). In particular, node sizes in ICs are being scaled down by a reduction in minimum gate length in the ICs (e.g., 65 nanometers (nm), 45 nm, 32 nm, 20 nm, <10 nm, etc.).

As a result, the gate lengths of planar transistors are also scalably reduced. For example, lithography gate cut process is currently used for creating components in ICs. Lithography gate cut, however, has critical dimensions (CD) limitations due to immersion lithography limitations that continue to reduce as pattern densities continue to increase. For example, the gate cut CD in the Y-direction for 32 nm is quite large because of 193i immersion lithography limitations. This is further described below with reference to FIGS. 1a and 1b. More specifically, the middle of line (MOL) contact pins area is reduced causing routing congestions. Furthermore, the smaller node sizes result in highly dense components that adversely impact device reliability, manufacturing yields, cost, and manufacturing times. Accordingly, there is a need for an apparatus and method for self-aligned gate cut semiconductor devices providing optimal power and routing at smaller nodes.

### SUMMARY

The following presents a simplified summary of one or more aspects to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

A semiconductor device is described. The semiconductor device may include a substrate, a gate region formed on the substrate, a self-aligned gate cut formed in the gate region, and a middle of line (MOL) area formed on the gate region, wherein the self-aligned gate cut provides critical dimensions in a range from 5 nm to 30 nm. The self-aligned gate cut reduces capacitance and power, provides flexibility in placement of the MOL area, and reduces local routing congestion.

A self-aligned process of manufacturing a semiconductor device is described. The method may comprise providing a substrate, forming a p-type field effect transistor (PFET) fin and an n-type field effect (NFET) fin in a gate region, etching a non-fin gate metal region and filling the non-fin gate region with a dielectric material, etching the dielectric material to partially remove the dielectric material, depositing a conformal layer over the gate region and the dielectric material, etching the conformal layer in the horizontal direction, depositing a layer of polysilicon on the semiconductor device, polishing the semiconductor device using chemical-mechanical polishing (CMP) to its approximate original height, etching the polysilicon layer, depositing high-k metal gate materials and forming middle of line (MOL) area on the gate region, wherein the self-aligned process provides critical dimensions in a range from 5 nm to 30 nm.

### BRIEF DESCRIPTION OF THE DRAWINGS

FIGS. 1a and 1b are top and cross-sectional views, respectively, of a gate cut of a semiconductor device of the prior art.

FIGS. 2a and 2b are top and cross-section views, respectively, of a self-aligned gate cut of a semiconductor device according to one aspect of the invention.

FIGS. 3a-3i illustrate a self-aligned process of manufacturing a semiconductor device according to one aspect of the invention.

### DETAILED DESCRIPTION

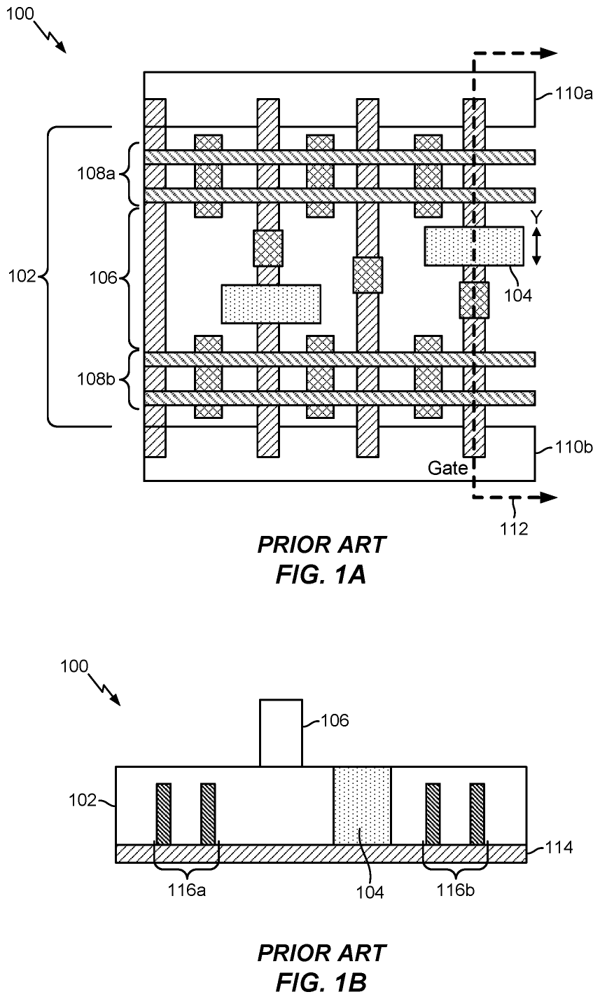

FIGS. 1a and 1b illustrate top and cross-section views, respectively, of a gate cut of a semiconductor device of the prior art. The semiconductor device may be a complementary metal oxide semiconductor (CMOS) device 100 used in a logical or digital circuit. For example, the CMOS device 100 may be included in an inverter, a logical NOR gate, a logical NAND gate, etc. The CMOS device 100 may include a p-type field effect transistor (PFET) and an n-type field effect transistor (NFET). The PFET may be a p-type FinFET, and the NFET may be an n-type FinFET. The CMOS device 100 may include a gate region 102, an isolation region 104, and a middle of line (MOL) area 106. The MOL area 106 may be used to form contacts for signals. In one aspect, the NFET portion of the CMOS device 100 may include a diffusion area 108a (NFET diffusion area), and the PFET portion of the CMOS device 100 may include a diffusion area 108b (PFET diffusion area). A source of the NFET portion may be included in the diffusion area 108a and may be coupled to a first power rail 110a. For example, the first power rail 110a may provide a supply voltage (Vdd) to the source of the NFET portion. A source of the PFET portion may be included in the diffusion area 108b and may be coupled to a second power rail 110b. For example, the second power rail 110b may provide a ground voltage (Vss) to the source of the PFET portion.

A common way of manufacturing the CMOS device 100 includes a gate cut by lithography process along arrow 112 in FIG. 1a, the cross-section view of which is shown in FIG. 1b. FIG. 1b further illustrates the CMOS device 100 including a substrate 114, MOL area 106 forming on top of gate region 102, and PFET fins 116a and NFET fins 116b formed in gate region 102. Gate region 102 may comprise polysilicon or high-k metal gate. The gate cut is a single patterning process to remove dummy transistors and reduce overall capacitance for low power applications. The size for the gate cut, however, needs to be at least 32 nm because it has critical dimensions (CD) limitations due to immersion lithography limitations. For example, the gate cut Y-direction CD is quite large at approximately 32 nm because of 193i immersion lithography limitations. In particular, the MOL area 106 is reduced after the gate cut causing routing congestions. That is, there is limited or less routing area for contact pins for the MOL area 106. Furthermore, the highly dense components may adversely impact device reliability, manufacturing yields, cost, and manufacturing times. Accordingly, there is a need for an improved gate cut semiconductor device different from lithography for optimal power and routing at lower nodes.

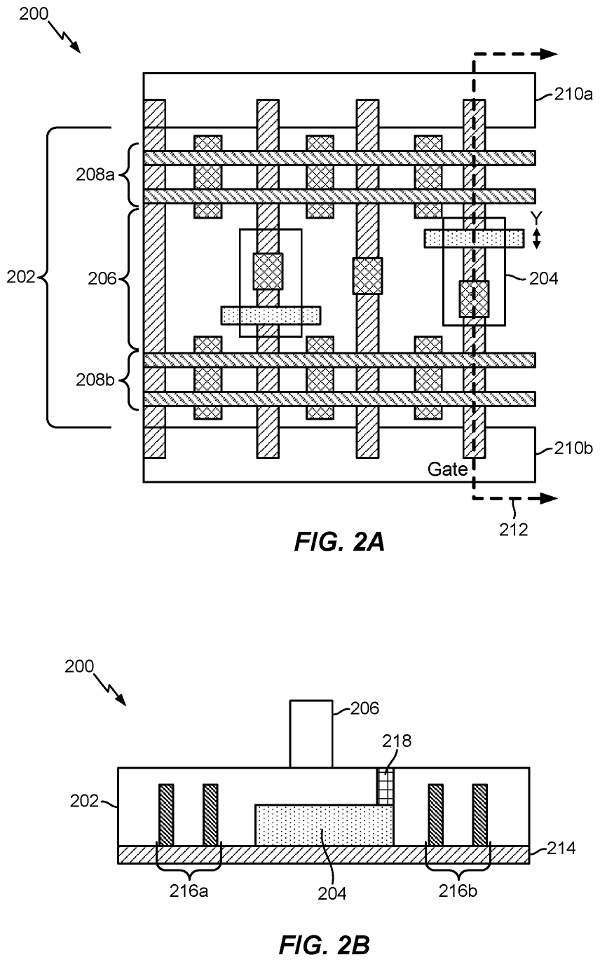

FIGS. 2a and 2b illustrate top down and cross-section views, respectively, of a self-aligned gate cut of a semiconductor device according to one aspect of the invention. The semiconductor device may be a complementary metal oxide semiconductor (CMOS) device 200 used in a logical or digital circuit. For example, the CMOS device 200 may be included in an inverter, a logical NOR gate, a logical NAND gate, etc. The CMOS device 200 may include a p-type field effect transistor (PFET) and an n-type field effect transistor (NFET). The PFET may be a p-type FinFET, and the NFET may be an n-type FinFET. The CMOS device 200 may include a gate region 202, an isolation region 204, and a middle of line (MOL) area 206. The MOL area 206 may be used to form contacts for signals. In one aspect, the NFET portion of the CMOS device 200 may include a diffusion area 208a (NFET diffusion area), and the PFET portion of the CMOS device 200 may include a diffusion area 208b (PFET diffusion area). A source of the NFET portion may be included in the diffusion area 208a and may be coupled to a first power rail 210a. For example, the first power rail 210a may provide a supply voltage (Vdd) to the source of the NFET portion. A source of the PFET portion may be included in the diffusion area 208b and may be coupled to a second power rail 210b. For example, the second power rail 210b may provide a ground voltage (Vss) to the source of the PFET portion.

A difference between CMOS device 200 and CMOS device 100 is CMOS device 200 is manufactured by a self-aligned gate cut instead of lithography gate cut as further described below. Advantages of the self-aligned gate cut include: smaller CD, i.e., CD direction size that may be controlled as low as 5 nm; a gate region that is only partially removed allowing more flexibility in placement of MOL pins; reduced capacitance and power; less expensive process; reduced local routing congestions; higher performance; and smaller area. In particular, CMOS device 200 may include a gate cut formed in the gate region 202 along arrow 212. Referring to FIG. 2g, the cross-section view illustrates a self-aligned gate cut 218 that only partially remove gate region 202 and, as a result, allowing more flexibility in placement of MOL pins and reducing local routing congestion for MOL area 206. CMOS device 200 may include a substrate 214, MOL area 206 formed on top of gate region 202, and PFET fin(s) 216a and NFET fin(s) 216b formed in gate region 202. Gate region 202 may comprise polysilicon or high-k metal gate. It should be noted that PFET fin(s) 216a and NFET fin(s) 216b may be one or more fin(s) depending on the fin structure and use. In one aspect, the self-aligned gate cut 218 provides a spacer to define the CD dimensions to control the it as low as 5 nm. In another aspect, the critical dimensions may be controlled from a range between 5 nm and 30 nm. It should be noted that the self-aligned gate cut is not an expensive process as compared to other advanced processes.

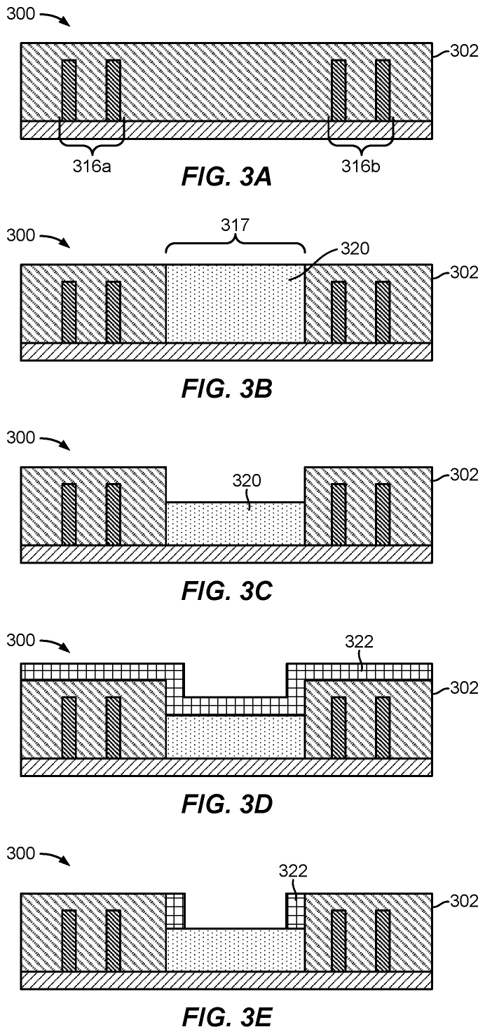

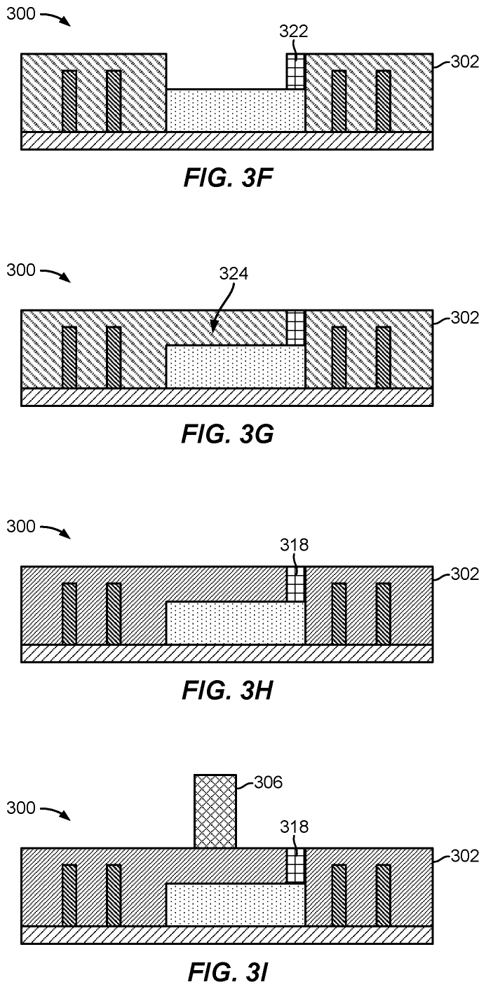

FIGS. 3a-3i illustrate a self-aligned process of manufacturing a semiconductor device 300 according to one aspect of the invention. CMOS device 300 with PFET fin(s) 316a and NFET fin(s) 316b may be formed in a gate region 302 as shown in FIG. 3a. Gate region 302 may comprise polysilicon. Next, non-fin gate metal regions 317 may be etched and filled with a dielectric material 320 such as SiN, SiO₂ as show in FIG. 3b. A chemical-mechanical polish (CMP) may then be used to polish or planarize CMOS device 300. The dielectric material 320 may be etched 322 to partially remove or recess the dielectric material 320 as shown in FIG. 3c. Next, CMOS device 300 is deposited with a conformal layer or insulator(s) 322 as shown in FIG. 3d. Conformal or insulator(s) 322 may comprise SiₓN_{y}, SiₓO_{y}, or SiₓN_{y}O_{z}. Conformal means approximately the same thickness everywhere including via(s) and sidewall(s). The conformal layer or insulator(s) 322 on the field (i.e., horizontal direction) may then be etched by anisotropic process as shown in FIG. 3e. That is, vertical direction conformal layer or insulator(s) 322 is not yet etched in FIG. 3e. Next, conformal or insulator(s) 322 in unwanted areas may then be etched using, e.g., deep ultraviolet (DUV) block masks, including those in vertical direction as shown in FIG. 3f. Another layer of polysilicon 324 may then be deposited on CMOS device 300 as shown in FIG. 3g, followed by CMP to polish or planarize CMOS device 300 to its original height. Polysilicon 324 may then be removed by wet etching and is later replaced by high-k metal gate materials as shown if FIG. 3h. MOL area 306 may then be formed in FIG. It should be noted that depositing of polysilicon layer 324 on CMOS device 300, followed by polishing or planarizing of CMOS device 300 by CMP to its original height, and then removing the polysilicon layer 324 by wet etching together form a self-aligned gate cut 318. The self-aligned process is very precise providing a spacer to define CD dimensions that may be controlled as low as 5 nm. Alternatively, the critical dimensions may be controlled from 5 nm to 30 nm. Moreover, the self-aligned gate cut 318 does not require expensive advanced process. In addition, the self-aligned gate cut provides more flexibility in placement of MOL pins and reduce local routing congestion for MOL area 306.

Those of skill would further appreciate that the various illustrative logical blocks, configurations, modules, circuits, and algorithm steps described in connection with the embodiments disclosed herein may be implemented as electronic hardware, computer software, or combinations of both. Various illustrative components, blocks, configurations, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary non-transitory (e.g. tangible) storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

1. A semiconductor device comprising:
a substrate;
a gate region formed on the substrate;
a self-aligned gate cut formed in the gate region; and
a middle of line (MOL) area formed on the gate region,
wherein the self-aligned gate cut provides critical dimensions in a range from 5 nm to 30 nm.

2. The semiconductor device of claim 1, wherein the semiconductor device is a complementary metal oxide semiconductor (CMOS) device.

3. The semiconductor device of claim 2, wherein the CMOS device further comprises a p-type field effect transistor (PFET) and an n-type field effect transistor (NFET).

4. The semiconductor device of claim 3, wherein the CMOS further comprises an NFET diffusion area and a PFET diffusion area.

5. The semiconductor device of claim 1, wherein the self-aligned gate cut reduces capacitance and power.

6. The semiconductor device of claim 1, wherein the self-aligned gate cut provides flexibility in placement of the MOL area and reduces local routing congestion.

7. The semiconductor device of claim 1, wherein the MOL area is used to form contacts for signals.

8. The semiconductor device of claim 3, wherein the CMOS device further comprises a PFET fin and an NFET fin formed in the gate.

9. The semiconductor device of claim 1, further comprising a device selected from the group consisting of a mobile phone, a personal digital assistant (PDA), a tablet, a music player, a video player, an entertainment unit, a navigation device, a communications device, a fixed location data unit, and a computer, into which the substrate, the gate region, the self-aligned gate cut, and the MOL area are integrated.

10-20. (canceled)
